(19) United States
(12) Patent Application Publication
(10) Pub. No.: US 2026/0169048 A1
(43) Pub. Date: Jun. 18, 2026

(54) COMPUTER SYSTEM AND COMPUTER-IMPLEMENTED METHOD FOR DETECTING CHANGES IN ISOLATION RESISTANCE IN A FLUID PATH OF A COOLING SYSTEM

(71) Applicant: VOLVO TRUCK CORPORATION, Göteborg (SE)

(72) Inventors: Rohan NEILSON, Västerås (SE); Dani BARKAH, Eskilstuna (SE)

(73) Assignee: VOLVO TRUCK CORPORATION, Göteborg (SE)

(21) Appl. No.: 19/410,235

(22) Filed: Dec. 5, 2025

(30) Foreign Application Priority Data
Dec. 16, 2024 (EP) 24220199.4

(51) Int. Cl. G01R 31/00; B60L 3/00; B60L 58/26; B60L 58/33; G01M 3/40; G01R 31/52; H01M 8/04007; H01M 8/04029; H01M 10/613; H01M 10/625; H01M 10/6567

(52) U.S. Cl. CPC G01R 31/007; B60L 3/0046; B60L 3/0053; B60L 3/0069; B60L 58/26; B60L 58/33; G01M 3/40; G01R 31/52; H01M 8/04029; H01M 8/04074; H01M 10/613; H01M 10/625; H01M 10/6567

(57) ABSTRACT

A computer system has processing circuitry to obtain first isolation resistance data associated with an isolation resistance between poles of a vehicle subsystem of a vehicle and a ground connection wherein a fluid path of a cooling system configured to cool the vehicle subsystem is in a first state, obtain second isolation resistance data associated with an isolation resistance between the poles and the ground connection wherein the fluid path is in a second state. The coolant in the fluid path is electrically energized at least in the second state. A change in isolation resistance is determined.

### TECHNICAL FIELD

The disclosure relates generally to computer systems and computer-implemented methods. In particular aspects, the disclosure relates to a computer system and a computer-implemented method for detecting changes in isolation resistance in a fluid path of a cooling system, e.g. a cooling system of a vehicle. The disclosure can be applied to heavy-duty vehicles, such as trucks, buses, and construction equipment, among other vehicle types. Although the disclosure may be described with respect to a particular vehicle, the disclosure is not restricted to any particular vehicle.

### BACKGROUND

In vehicles and in particular electric vehicles, managing thermal and electrical safety is increasingly important. Improving the integrity of cooling systems for components like traction batteries and electric motors may be of great importance, as there is a risk of the coolant carrying electrical currents, which could be hazardous.

Existing solutions often involve costly conductivity sensors that may not be reliable due to contamination. Additionally, traditional isolation resistance monitoring systems might not effectively assess components that are usually isolated, leading to undetected voltage leaks into the cooling system.

Current technologies frequently focus on measuring coolant conductivity but may not address grounding issues or detect voltage leaks comprehensively. These limitations suggest a need for more efficient and cost-effective monitoring approaches that can better utilize existing systems to improve safety and performance in vehicle operations.

### SUMMARY

According to a first aspect of the disclosure a computer system is provided. The computer system comprises processing circuitry configured to: obtain first isolation resistance data associated with an isolation resistance between poles of a vehicle subsystem of a vehicle and a ground connection wherein a fluid path of a cooling system configured to cool the vehicle subsystem is in a first state, obtain second isolation resistance data associated with an isolation resistance between the poles and the ground connection wherein the fluid path is in a second state, wherein coolant in the fluid path is electrically energized at least in the second state, and determine a change in isolation resistance between the poles and the ground connection based on the first and second isolation resistance data, and generate control data for the vehicle based on the determined change. The first aspect of the disclosure may seek to detect potential faults in in a vehicle subsystem. A technical benefit may include providing a less complex and more cost efficient manner of monitoring coolant conductivity and system integrity efficiently.

Optionally in some examples, including in at least one preferred example, the processing circuitry may be further configured to obtain fluid path resistance data associated with the electrical resistance of the fluid path, and generate control data for the vehicle based on the determined change in isolation resistance and the fluid path resistance data. A technical benefit may include detecting such coolant conductivity and potential leaks in a simple, robust and cost effective manner.

Optionally in some examples, including in at least one preferred example, the processing circuitry may be further configured to responsive to the determined change in isolation resistance being outside a fluid path isolation resistance threshold, determine at least one of that the fluid path leaks into the vehicle subsystem and that contamination has occurred in the vehicle subsystem. A technical benefit may include early detection of leaks or contaminations to prevent damage to vehicle components.

Optionally in some examples, including in at least one preferred example, the processing circuitry may be further configured to responsive to the determined change in isolation resistance being outside a fault resistance threshold determine that a fault is present in at least one of the vehicle subsystem and the vehicle cooling system, A technical benefit may include identifying and addressing a fault in the vehicle cooling system or vehicle subsystem to improve safety.

Optionally in some examples, including in at least one preferred example, the processing circuitry may be further configured to responsive to the determined change in isolation resistance being outside a ground connection isolation resistance threshold, determine a faulty cooling system ground connection of the cooling system. A technical benefit may include identifying and addressing faulty connections to improve safety.

Optionally in some examples, including in at least one preferred example, the processing circuitry may be further configured to obtain the fluid path resistance data based on geometrical characteristics of the fluid path and/or characteristics of the coolant. A technical benefit may include providing more precise diagnostics based on specific system characteristics.

Optionally in some examples, including in at least one preferred example, the processing circuitry may be further configured to obtain a diagnostic or fault tracing command, and responsive to the diagnostic or fault tracing command cause a switch between the first and second state. A technical benefit may include enabling targeted diagnostics and maintenance interventions.

Optionally in some examples, including in at least one preferred example, the processing circuitry may be further configured to cause a change between the first and the second state via a probe exposed to the coolant. A technical benefit may include allowing for isolation resistance monitoring in a simple and cost effective manner.

Optionally in some examples, including in at least one preferred example, the processing circuitry may be further configured to energize the coolant in the fluid path via the probe exposed to the coolant to cause a change in energization between the first state and the second state. A technical benefit may include allowing for isolation resistance monitoring in a simple and cost effective manner.

Optionally in some examples, including in at least one preferred example, the processing circuitry may be further configured to control a flow adjusting device arranged in the fluid path to cause a change in the geometric characteristics of the coolant path between the first state and the second state. A technical benefit may include allowing for isolation resistance monitoring in a simple and cost effective manner.

According to a second aspect of the disclosure, a vehicle is provided. The vehicle comprises the computer system of any of examples described herein. The second aspect of the disclosure may seek to solve the problem of integrating a system that detects and responds to changes in isolation resistance within the vehicle's cooling and electrical systems. A technical benefit may include enabling vehicles to automatically adjust and respond to changes in system integrity, improving safety and reliability.

Optionally in some examples, including in at least one preferred example, the vehicle may further comprise an isolation monitoring device operatively connected to the processing circuitry and configured to measure the isolation between the poles and the ground connection to provide the first and second isolation resistance data. A technical benefit may include enhancing the accuracy of isolation resistance measurements, thereby allowing for more reliable system diagnostics.

Optionally in some examples, including in at least one preferred example, the vehicle may further comprise a switch selectively connecting a probe to a potential of the vehicle subsystem, such as the poles, wherein the processing circuitry is operatively connected to the switch to control said switch to selectively energize the probe to thereby energize the coolant. A technical benefit may be to bypass insulation allowing fluid that is not normally energized to be assessed.

Optionally in some examples, including in at least one preferred example, the vehicle may further comprise a set resistance arranged between the probe and a power source for energizing the probe. A technical benefit may include promoting safe current levels during probe energization, thereby enhancing the safety of the vehicle's electrical systems.

Optionally in some examples, including in at least one preferred example, the vehicle may further comprise at least one fuel cell system forming the vehicle subsystem. A technical benefit may include allowing for identifying potential issues relating to isolation resistance in a fuel cell system.

Optionally in some examples, including in at least one preferred example, the vehicle may further comprise at least one battery system forming the vehicle subsystem. A technical benefit may include allowing for identifying potential issues relating to isolation resistance in a battery system.

Optionally in some examples, including in at least one preferred example, the battery system may comprise one or more immersion cooled batteries and the cooling system is provided as an immersion cooling system. A technical benefit may include allowing for identifying potential issues relating to isolation resistance in an immersion cooled battery system.

Optionally in some examples, including in at least one preferred example, the vehicle may further comprise a shielding, conductor or collector plate, wherein said shielding, conductor or collector plate forms the probe and is arranged adjacent to an area of similar voltage potential of the one or more immersion cooled batteries. A technical benefit may include to enable utilization of commonly occurring components of an immersion cooled battery system for the generation of the control data based on the change in isolation resistance allowing for a less complex and more cost efficient computer system and vehicle subsystem.

Optionally in some examples, including in at least one preferred example, the vehicle may further comprise at least one motor drive system forming the vehicle subsystem. A technical benefit may include allowing for identifying potential issues relating to isolation resistance in a motor drive system. Another technical benefit may include specifically identifying fluid ingress, e.g. water ingress, or direct cooling fluid degradation prior to winding insulation failure.

Optionally in some examples, including in at least one preferred example, the vehicle may further comprise at least one battery system and/or fuel cell system forming the vehicle subsystem, wherein the processing circuitry is further configured to: energizing the coolant in the fluid path via a probe exposed to the coolant to cause a change in energization between the first state and the second state, obtain fluid path resistance data associated with the electrical resistance of the fluid path, generate control data for the vehicle based on the determined change in isolation resistance and the fluid path resistance data, and responsive to the determined change in isolation resistance being outside a fluid path isolation resistance threshold, determine at least one of that the fluid path leaks into the vehicle subsystem and that contamination has occurred in the vehicle subsystem. A technical benefit may include providing comprehensive monitoring and control of vehicle subsystems, which enhances operational safety and system reliability.

According to a third aspect of the disclosure, a computer-implemented method is provided. The computer-implemented method comprises obtaining, by processing circuitry of a computer system, first isolation resistance data associated with an isolation resistance between poles of a vehicle subsystem of a vehicle and a ground connection wherein a fluid path of a cooling system configured to cool the vehicle subsystem is in a first state, obtaining, by the processing circuitry, second isolation resistance data associated with an isolation resistance between the poles and the ground connection wherein the fluid path is in a second state, wherein coolant in the fluid path is electrically energized in at least the second state, determining, by the processing circuitry, a change in isolation resistance between the poles and the ground connection based on the first and second isolation resistance data, and generating, by the processing circuitry, control data for the vehicle based on the determined change. The third aspect of the disclosure may seek to detect potential faults in a vehicle subsystem. A technical benefit may include providing a less complex and more cost efficient manner of monitoring coolant conductivity and system integrity efficiently.

Optionally in some examples, including in at least one preferred example, the method may further comprise obtaining, by the processing circuitry, fluid path resistance data associated with the electrical resistance of the fluid path, and generating, by the processing circuitry, control data for the vehicle based on the determined change in isolation resistance and the fluid path resistance data. A technical benefit may include enhancing the precision of control data generation by incorporating fluid path resistance measurements.

Optionally in some examples, including in at least one preferred example, the method may further comprise responsive to the determined change in isolation resistance being outside a coolant isolation resistance threshold, determine, by the processing circuitry, at least one of that the fluid path leaks into the vehicle subsystem and that contamination has occurred in the vehicle subsystem. A technical benefit may include providing early detection capabilities for leaks or contaminations, thereby potentially preventing potential damage and improving the safety of the vehicle subsystem.

According to a fourth aspect of the disclosure, a computer program product is provided. The computer program product comprises program code for performing, when executed by the processing circuitry, the method of any of the examples described herein. The fourth aspect of the disclosure may seek to enable new vehicles and/or legacy vehicles to be conveniently configured, by software installation/update, to monitor and manage isolation resistance changes in vehicle systems. A technical benefit may include offering a software-based solution that enhances system monitoring capabilities without significant hardware changes.

According to a fifth aspect of the disclosure, a non-transitory computer-readable storage medium is provided. The non-transitory computer-readable storage medium comprises instructions, which when executed by the processing circuitry, cause the processing circuitry to perform the method of any of the examples described herein. The fifth aspect of the disclosure may seek to enable new vehicles and/or legacy vehicles to be conveniently configured, by software installation/update, to enhance system safety and reliability through improved monitoring technologies. A technical benefit may include providing a flexible and scalable approach to implement system monitoring and control solutions.

The disclosed aspects, examples (including any preferred examples), and/or accompanying claims may be suitably combined with each other as would be apparent to anyone of ordinary skill in the art. Additional features and advantages are disclosed in the following description, claims, and drawings, and in part will be readily apparent therefrom to those skilled in the art or recognized by practicing the disclosure as described herein.

There are also disclosed herein computer systems, control units, code modules, computer-implemented methods, computer readable media, and computer program products associated with the above discussed technical benefits.

### BRIEF DESCRIPTION OF THE DRAWINGS

Examples are described in more detail below with reference to the appended drawings.

FIG. 1 is an exemplary side view of a vehicle according to an example.

FIG. 2A is an exemplary system diagram of a vehicle subsystem and computer system according to an example.

FIG. 2B is an exemplary system diagram of a vehicle subsystem and computer system according to an example.

FIG. 3 is an exemplary vehicle subsystem and cooling system according to an example.

FIG. 4 is an exemplary vehicle subsystem and cooling system according to an example.

FIG. 5 is an exemplary vehicle subsystem and cooling system according to an example.

FIG. 6 is an exemplary vehicle subsystem and cooling system according to an example.

FIG. 7 is a flow chart of an exemplary method according to an example.

FIG. 8 is a schematic diagram of an exemplary computer system for implementing examples disclosed herein, according to an example.

### DETAILED DESCRIPTION

The detailed description set forth below provides information and examples of the disclosed technology with sufficient detail to enable those skilled in the art to practice the disclosure.

In the following various examples will be given all related to the general idea of comparing an isolation resistance associated with a first state of a fluid path of a cooling system and an isolation resistance associated with a second state of the same fluid path. By comparing these isolation resistance data, it is possible to cause actions based on the findings. For example, an effective coolant conductivity of the fluid path may be determined, it may be determined whether the cooling system is grounded or whether voltage is leaking into the cooling system.

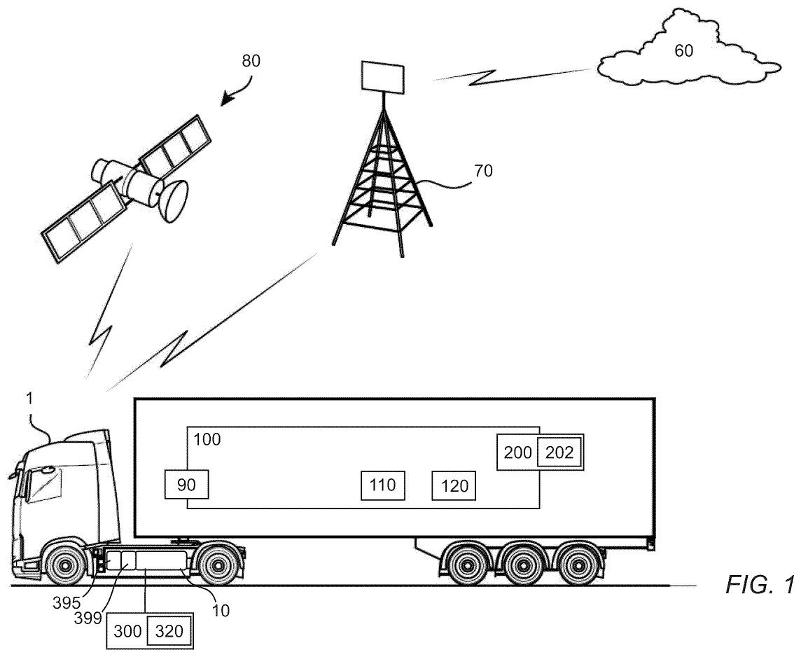

FIG. 1 is an exemplary view of a vehicle 1 according to one example. The vehicle 1 comprises at least one isolation resistance monitoring system 200. The at least one isolation resistance monitoring system 200 is configured to determine changes in the isolation resistance of a vehicle subsystem 10. In particular, the isolation resistance monitoring system 200 is configured to determine such changes associated with changes in the state, e.g. operation, of a fluid path 320 of a cooling system 300 of the vehicle 1. The cooling system 300 is configured to cool the vehicle subsystem 10.

For example, the fluid path 320 may form a part of the vehicle subsystem 10. The fluid path 320 may extend between the vehicle subsystem 10 and a pump 395 and/or a radiator 399. The vehicle 1 is programmed to control the isolation resistance monitoring system 200, as will be described further in the following.

As will be explained in further detail later on, the vehicle subsystem 10 may for example be formed by at least one fuel cell system, at least one battery system or at least one motor drive system of the vehicle 1.

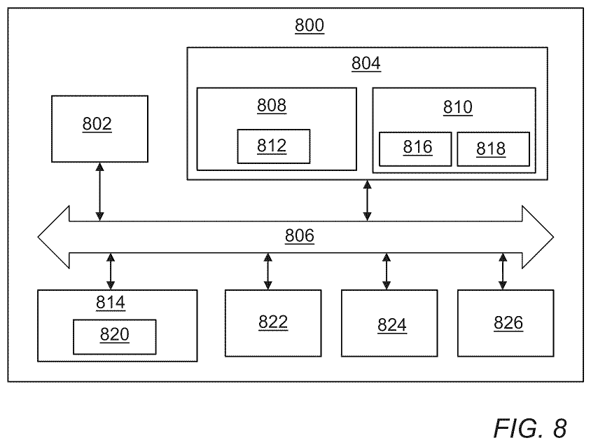

The vehicle 1 comprises, at least to some extent, processing circuitry 110 forming part of a computer system 100 (see FIG. 8). The processing circuitry 110 is configured to implement the isolation resistance monitoring system 200.

The vehicle 1 may further comprise communications circuitry 90 configured to receive and/or send communications. The communications circuitry 90 may be configured to enable the vehicle 1 to communicate with one or more external devices or systems such as a cloud server 60. The communication with the external devices or systems may be directly or via a communications interface such as a cellular communications interface 70, such as a radio base station. The cloud server 60 may be any suitable cloud server exemplified by, but not limited to, Amazon Web Services (AWS), Microsoft Azure, Google Cloud Platform (GCP), IBM Cloud, Oracle Cloud Infrastructure (OCI), DigitalOcean, Vultr, Linode, Alibaba Cloud, Rackspace etc. The communications interface may be a wireless communications interface exemplified by, but not limited to, Wi-Fi, Bluetooth, Zigbee, Z-Wave, LoRa, Sigfox, 2G (GSM, CDMA), 3G (UMTS, CDMA2000), 4G (LTE), 5G (NR) etc. The communication circuitry 90 may, additionally or alternatively, be configured to enable the vehicle 1 to be operatively connected to a Global Navigation Satellite System (GNSS) 80 exemplified by, but not limited to, global positioning system (GPS), Globalnaya Navigatsionnaya Sputnikovaya Sistema (GLONASS), Galileo, BeiDou Navigation Satellite System, Navigation with Indian Constellation (NavIC) etc. The vehicle 1 may for example be configured to utilize data obtain from the GNSS 80 to determine a geographical location of the vehicle 1.

The vehicle 1 in FIG. 1 comprises the computer system 100 and the isolation resistance monitoring system 200. The computer system 100 may be operatively connected to the isolation resistance monitoring system 200 and optionally to the communications circuitry 90 of the vehicle 1. The computer system 100 comprises processing circuitry 110. The computer system 100 may comprise a storage device 120, advantageously a non-volatile storage device such as a hard disk drives (HDDs), solid-state drives (SSDs) etc. In some examples, the storage device 120 is operatively connected to the computer system 100. The isolation resistance monitoring system 200 may comprise isolation resistance monitoring system processing circuitry 202; the isolation resistance monitoring system processing circuitry 202 may be part of the processing circuitry 110 of the computer system 100.

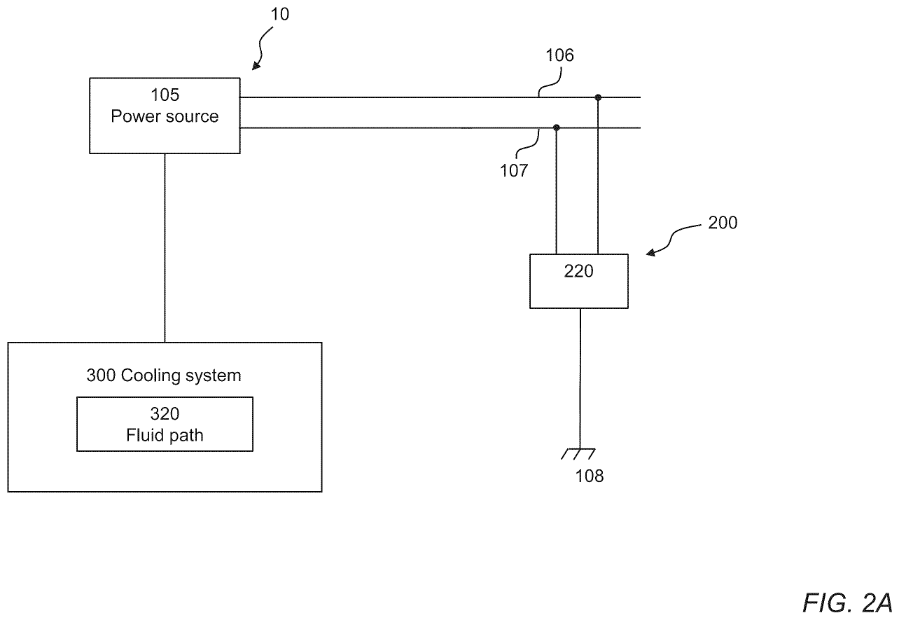

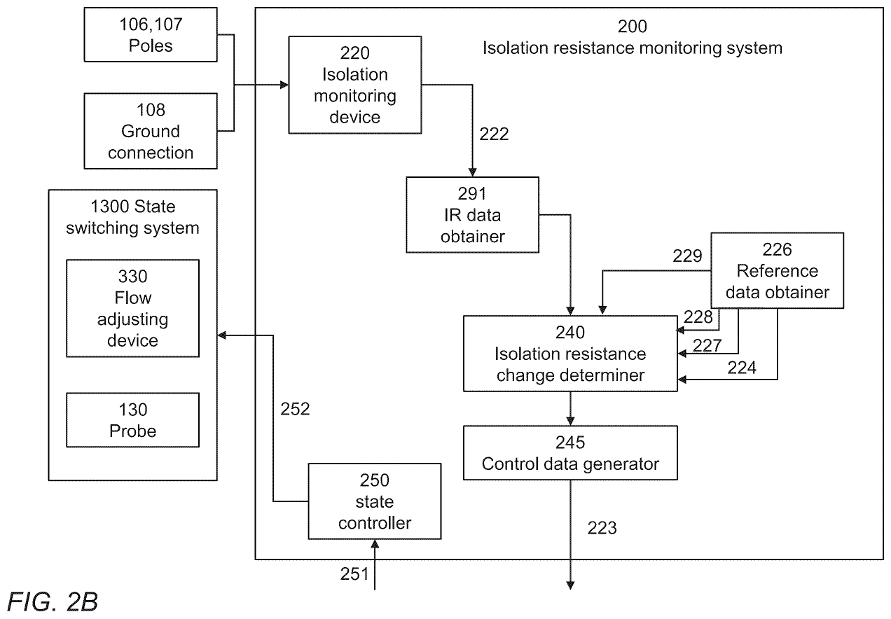

An example of a vehicle subsystem 10 is shown in FIG. 2A. The vehicle subsystem 10 is configured to be monitored by an isolation resistance monitoring system 200, which in the shown example is at least partly embodied by an isolation resistance monitoring device 220.

The processing circuitry 110, in FIG. 2A embodied by the isolation resistance monitoring system 200 and in particular the isolation resistance monitoring device 220, is configured obtain isolation resistance data. The isolation resistance data is associated with an isolation resistance between poles 106, 107 of the vehicle subsystem 10, e.g. a power source 105 of the vehicle subsystem 10, and a ground connection 108.

The processing circuitry 110, in FIG. 2A embodied by the isolation resistance monitoring system 200 and in particular the isolation resistance monitoring device 220, is configured to obtain first isolation resistance data associated with the isolation resistance between the poles 106, 107 and the ground connection 108 where the fluid path 320 operates in a first state. Correspondingly, the processing circuitry 110, in FIG. 2A embodied by the isolation resistance monitoring system 200 and in particular the isolation resistance monitoring device 220, is configured to obtain second isolation resistance data associated with the isolation resistance between the poles 106, 107 and the ground connection 108 where the fluid path 320 operates in a second state.

At least in the second state, coolant in the fluid path 320 is electrically energized. Accordingly, the coolant may be subjected to an electric current.

The processing circuitry 110, in FIG. 2A embodied by the isolation resistance monitoring system 200 and in particular the isolation resistance monitoring device 220, is further configured to determine a change in isolation resistance between the poles 106, 107 and the ground connection 108 based on the first and second isolation resistance data and generate control data for the vehicle 1 based on the determined change.

The change in isolation resistance in view of the preset first and second state may be indicative of leakage of the fluid path 320 into the vehicle subsystem 10 or a fault in the vehicle subsystem 10 or the cooling system 300, for example a faulty ground connections for the components of the cooling system 300. The change in isolation resistance may be indicative of contamination, e.g. contamination by a conductive medium, of the vehicle subsystem 10.

In some examples, the coolant in the fluid path 320 may be energized in both the first and the second state. According to such examples, the fluid path 320 may be energized to a different degree in the first respectively second state. Alternatively, the fluid path 320 may be energized to the same or different degrees in the first and second state and also be subjected to changes being associated with a change in the isolation resistance data. For example, the geometric characteristics and/or properties of the coolant in the fluid path 320 may be changed between the first state and the second state. In some examples, the coolant is only energized in the second state.

Notably, the coolant in the fluid path 320 being energized may herein refer to only a portion of the coolant in the fluid path 320 being energized or all of the coolant in the fluid path being energized. It may for example be envisioned that only the coolant in present in a delimited section of the fluid path 320 is energized.

The isolation resistance monitoring system 200 may be provided within the vehicle subsystem 10. The isolation resistance monitoring system 200 may be configured to assess the isolation resistance between poles 106, 107 of the vehicle subsystem 10 and a ground connection 108. This system could potentially be embodied by the isolation resistance monitoring device 220, forming a part of a comprehensive monitoring setup. The function of this system may be to identify unintended electrical paths that could lead to faults or pose safety risks.

The processing circuitry 110, which in some examples may integrate the isolation resistance monitoring system 200, may be configured to obtain isolation resistance data. This data acquisition could occur under different operational states of a fluid path 320, utilized in the cooling system 300 of the vehicle subsystem 10. The data might be categorized as first and second isolation resistance data, corresponding to the different states of the fluid path 320, potentially indicating changes in coolant conditions or system integrity.

The vehicle subsystem 10 may include various power sources 105, such as a battery cell system, a fuel cell stack, or other energy storage solutions commonly used in vehicles and in particular electric vehicles.

Upon determining a change in isolation resistance, the processing circuitry 110 may generate control data for the vehicle 1. This control data could be employed to adjust vehicle operations, thereby maintaining safety and performance. For instance, significant changes in isolation resistance could trigger alerts, adjust cooling system parameters, or alter power distribution among subsystems to mitigate potential damage or safety risks.

In FIG. 2A, the isolation resistance monitoring device 220 may be configured to measure the resistance to leakage between the poles 106, 107 and the ground connection 108 through a multitude of leakage paths which may be combined into a pair of combined total isolation resistances.

To exemplify, where no connection between the cooling system 300, e.g. the fluid path 320, and the ground connection 108 exists, whether the cooling system 300, e.g. the fluid path 320, is energized and to what level may be viewed as the product of the connections to the power source 105 and to the ground connection 108.

In some cases there may be no connection between the cooling system 300, e.g. the fluid path 320, and the ground connection 108 (the resistance may be near infinite/negligibly high) and whereby the connection may be created by switching between the first and the second state to create a change (such that potential leakage through cooling system becomes real and detectable).

In other cases, the cooling system 300, e.g. the fluid path 320, (or parts thereof) may not be connected to the power source 105 but may connect to the ground connection 108. In such cases, the cooling system 300, e.g. the fluid path 320, may be connected to the power source 105 thereby providing for turning a potential leak path into a real and measurable one.

In other cases this may be performed by shorting resistances.

Overall, this system may provide a monitoring approach that enhances a vehicle's capability to maintain operational safety and efficiency by proactively detecting irregularities by monitoring changes in the isolation resistance of the vehicle subsystem caused by induced changes in the cooling system, e.g. a fluid path of the cooling system.

For example, if a large drop in isolation resistance may occur when leakage current is allowed to flow through a coolant intended to cool a fuel cell system, this may indicate a high coolant conductivity. The processing circuitry may thus be configured to generate control data for shutting down the fuel cell system to prevent electrolysis of the coolant (even if the isolation resistance is still tolerable).

If the isolation resistance drops significantly when a leakage path is created through for example the coolant intended to cool a battery system such as an immersion cooled battery system, the processing circuitry may be configured to generate control data for shutting down one or more of batteries of the battery system. In some cases, all connected batteries may need to be shut-down.

If the isolation resistance drops significantly when a leakage path is created through an air gap in a vehicle subsystem in the form of a dry motor or through the fluid in a vehicle subsystem in the form of a direct liquid cooled motor, this may indicate water ingress or mechanical failure (e.g. Metal dust etc.). This may go undetected because the winding insulation/encapsulation prevents leakage but water and debris are common causes of winding faults, therefore detecting these root causes and servicing or repair may save the motor and may prevent sudden unexpected faults. Accordingly, the processing circuitry may be configured to generate an alert to an operator indicating a need for service or repair of the motor.

FIG. 2B shows a further example of a vehicle subsystem 10.

The isolation resistance monitoring system 200 may comprise an isolation resistance data obtainer 291. The isolation resistance data obtainer 291 may be configured to obtain the isolation resistance data 222. In the depicted example, the isolation resistance data obtainer 291 may be configured to obtain the isolation resistance data 222, e.g. the first and second isolation resistance data 222, from the isolation monitoring device 220.

The isolation resistance monitoring system 200 may comprise an isolation resistance change determiner 240. Isolation resistance change determiner may be configured to determine the change in isolation resistance based on, e.g. between, the first and second isolation resistance data 222.

The isolation resistance monitoring system 200 may comprise a control data generator 245. The control data generator 245 may be configured to generate control data 223 for the vehicle 1 based on the determined change, e.g. the change determined by the isolation resistance change determiner 240.

In one example, the processing circuitry 110, e.g. the isolation resistance monitoring system 200, may be configured to responsive to the determined change in isolation resistance being outside a fluid path isolation threshold, determine that the fluid path 320 leaks into the vehicle subsystem 10.

In one example, the processing circuitry 110, e.g. the isolation resistance monitoring system 200, may be configured to responsive to the determined change in isolation resistance being outside a fluid path isolation threshold, determine that contamination has occurred in the vehicle subsystem 10. Such a contamination may be in the form of an air or oil gap in the vehicle subsystem 10 being subjected to a contamination in the form of a fluid leaking into said air or oil gap. The fluid may cause the air or oil gap conducting.

For example, an air or oil cell of the vehicle subsystem 10 may be selectably energized against within a grounded enclosure. For example, considering an example where normally isolated coolant has leaked into the enclosure; when the air gap is tested for impact on isolation the higher-than-expected change may indicate a fault. This could be condensed water vapor or a flood or water leak from outside, or a coolant leak, or debris from a failing component.

The processing circuitry 110, e.g. the isolation resistance monitoring system 200, may be configured to obtain fluid path resistance data 229. The fluid path resistance data 229 may be associated with the electrical resistance of the fluid path 320. The processing circuitry 110, e.g. the isolation resistance monitoring system 200, may be configured to generate control data for the vehicle 1 based on the determined change in isolation resistance and the fluid path resistance data 229. The fluid path resistance data 229 may be in the form of a pole resistance to ground in Ohm, such as a positive and negative pole resistance.

Typically, the resistance in parallel may be added or subtracted for obtaining a change affecting the total (between the first and second state). The total resistance may calculated as follows:

$$\frac{1}{{R}_{T o t a l}} = \frac{1}{{R}_{1}} + \frac{1}{{R}_{2}} ;$$

wherein Rₜₒₜₐₗ is the total resistance, e.g. measured total resistance, R₁ is the last total resistance, e.g. the total resistance associated with the first state and R₂ is the unknown resistance, e.g. the total resistance associated with the second state.

The isolation resistance monitoring system 200 may comprise a reference data obtainer 226. The reference data obtainer 226 may be configured to obtain the fluid path resistance data 229. The fluid path resistance data 229 may be provided as reference data, for example stored in storage device 120 of the computer system 100. The fluid path resistance data 229 may be in the form of a resistance value associated with the fluid path. The value may be a calculated value obtained by a model of the fluid path 320 and/or a historic measured value of the resistance of the fluid path 320. In one example, the reference data obtainer 226 may be configured to obtain the last total resistance, e.g. the total resistance associated with the first state.

The processing circuitry 110, e.g. the isolation resistance monitoring system 200, may be configured to responsive to the determined change in isolation resistance being outside a fault resistance threshold, determine that a fault is present in at least one of the vehicle subsystem 10 and the cooling system 300.

The processing circuitry 110, e.g. the isolation resistance monitoring system 200, may be configured to responsive to the determined change in isolation resistance being outside a ground connection isolation resistance threshold, determine a faulty cooling system ground connection of the cooling system.

The reference data obtainer 226 may be configured to obtain the ground connection isolation resistance threshold 228. The ground connection isolation resistance threshold 228 may be provided as an interval or upper or lower threshold indicative of a faulty cooling system ground connection. The ground connection isolation resistance threshold 228 may be provided as reference data, for example stored in storage device 120 of the computer system 100.

The processing circuitry 110, e.g. the isolation resistance monitoring system 200, may be configured to obtain the fluid path resistance data based on geometrical characteristics of the fluid path 320 and/or characteristics of the coolant. The reference data obtainer 226 may be configured to obtain the fluid path resistance data 229 based on the geometrical characteristics 227 and/or the characteristics of the coolant 224. The geometrical characteristics 227 and/or the characteristics of the coolant 224 may be provided as reference data, for example stored in storage device 120 of the computer system 100.

The geometrical characteristics may comprise length data associated with the length L of the fluid path 320 and area data associated with the cross-section area A of the fluid path 320. From the path geometry, e.g. the length and area, a path resistance a may be calculated as follows:

$$σ = L / ( R \cdot A ) ;$$

However, as these values may be complex, the calculation of the conductivity may be simplified by utilizing a single constant or coefficient C relating the path resistance to conductivity. The single constant or coefficient may be calculated as follows:

$$C = \frac{L}{A}$$

The processing circuitry 110, e.g. the isolation resistance monitoring system 200, may be configured to obtain a diagnostic or fault tracing command 251. In response to the diagnostic or fault tracing command 251, the processing circuitry 110, e.g. the isolation resistance monitoring system 200, may be configured to cause a switch between the first and second state. The diagnostic or fault tracing command 251 may be obtained from the computer system 100 and/or a user interface operatively connected to the computer system 100. Preferably, the processing circuitry 110 may be configured to cause operation in the first state and in response to the diagnostic or fault tracing command, cause a switch to the second state. Additionally or alternatively, the processing circuitry 110 may be configured to cause a switch between the first and the second state, e.g. from the first state to the second state, within set time intervals. Thereby, an automated check may be performed at regular intervals.

Accordingly, operation in the first state may be considered a normal state which may be switched to the second state upon a check of the vehicle subsystem 10 or the cooling system 300 is to be performed.

The isolation resistance monitoring system 200 may comprise a state controller 250 configured to cause the switch between the first and second state. In the depicted example, the state controller 250 is configured to obtain the diagnostic or fault tracing command 251 and cause a switch between the first and second state in response to said diagnostic or fault tracing command 251.

The vehicle 1, e.g. the vehicle subsystem 10 may comprise a state switching system 1300. The state switching system 1300 is configured to switch the state of the cooling path 320 between the first and second state. The isolation resistance monitoring system 200 and preferably the state controller 250 may be operatively connected to said state switching system 1300 and may be configured to control the state switching system 1300. The state controller 250 may be configured to generate state control data 252 for the control the state switching system 1300.

As will be described in further detail later on, the state switching system 1300 may be designed in a plurality of ways. The state switching system 1300 may comprise one or more components controllable to achieve the first and second state of the fluid path 320.

In one example, the processing circuitry 110, e.g. the isolation resistance monitoring system 200, may be configured to cause a change between the first and the second state via a probe 130 exposed to the coolant.

In one example, the processing circuitry 110, e.g. the isolation resistance monitoring system 200, may be configured to energize the coolant in the fluid path 320 via the probe 130. The probe 130 may be exposed to the coolant, e.g. the coolant in the fluid path 320, to cause a change in energization between the first and second state. The state switching system 1300 may thus comprise the probe 130.

In one example, the processing circuitry 110, e.g. the isolation resistance monitoring system 200, may be configured to control a flow adjusting device 330. The flow adjusting device 330 may be arranged in the fluid path 320 to cause a change in the geometric characteristics of the coolant path 320 between the first and second state. The state switching system 1300 may thus comprise the flow adjusting device 330.

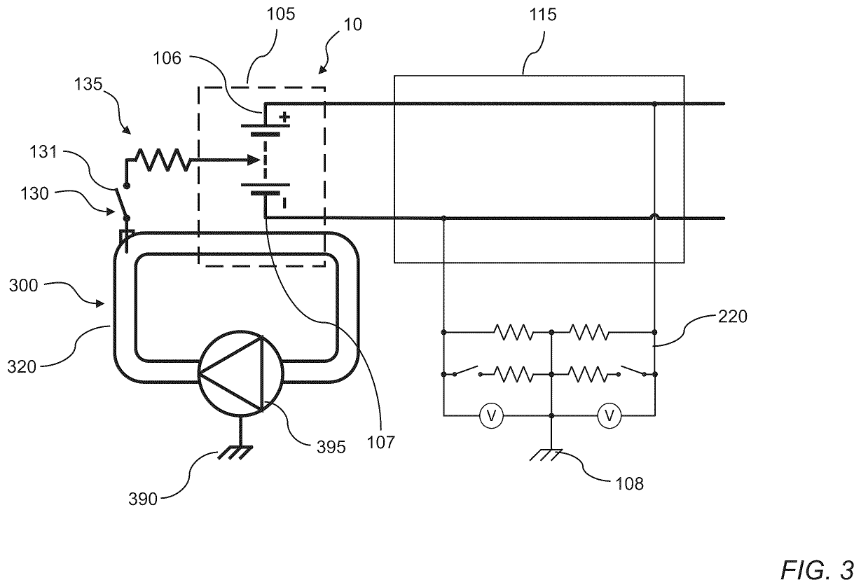

FIG. 3 illustrates a schematic representation of a vehicle subsystem 10, incorporating the cooling system 300 designed to manage thermal conditions within the vehicle subsystem 10. The cooling system comprises the fluid path 320, through which coolant circulates, facilitated by the pump 395. The fluid path 320 serves the function of maintaining desirable temperatures and enabling efficient operation of the vehicle subsystem 10.

The vehicle 1, e.g. the vehicle subsystem 10 may comprise the isolation monitoring device 220. The isolation monitoring device 220 may operatively connected to the processing circuitry 110. In one example, the isolation monitoring device 220 may be at least partly implemented by the processing circuitry 110. The isolation monitoring device 220 may be configured to measure the isolation between the poles 106, 107 and the ground connection 108. The isolation monitoring device 220 may be provide the first and second isolation resistance data. The isolation monitoring device 220 may thus serve to assess the electrical integrity of the subsystem.

In FIG. 3, the isolation monitoring device 220 measures the isolation resistance between the poles 106, 107 and the ground connection 108 through a system of bridges, switches, known resistances, and voltage sensors. Notably, the depicted isolation monitoring device 220 is for exemplary purposes only and may as the skilled person recognizes be implemented in a plurality of ways.

The isolation monitoring device 220 may operate by first establishing a baseline isolation resistance when the fluid path 320 is in its initial state. It may employ known resistances and strategically placed voltage sensors to accurately measure the voltage drop across these elements. By activating switches within the bridge circuit, the device can selectively connect or disconnect certain paths, enabling precise control and measurement of electrical parameters.

In FIG. 3, the isolation monitoring device 220 is implemented as an Isolation/Insulation Resistance Monitoring Device (IRM/IMD). The IRM/IMD may also integrate additional functionalities directly within the device, rather than relying on external components. Thus, the change in isolation resistance may be measured by the IRM/IMD in a manner that would otherwise require dedicated excitation and measurement circuitry to obtain.

It may be envisioned that the isolation monitoring device 220 may be configured to employ alternative methods for measuring the isolation resistance.

In the example of FIG. 3, the fluid path 320 of the cooling system 300 may be energized, whereby the isolation monitoring device 220 may be configured to measure a resulting potential change in isolation resistance between the poles 106, 107 and the ground connection 108. In the example of FIG. 3, the power source 105 may normally be insulated from the coolant, whereby a connection may be created for the purpose of detecting the change in isolation resistance.

Accordingly, in the first state, the fluid path 320 may not be energized by means of the power source 105 while in the second state, the fluid path 320 may be energized by means of the power source 105. As the coolant within the fluid path 320 transitions to an energized state, the isolation monitoring device 220 continues to measure the isolation resistance. This continuous monitoring capability may allow for the isolation monitoring device 220 to detect changes in isolation resistance, which could indicate potential faults or leaks. By providing real-time data to the processing circuitry 110, e.g. the isolation resistance monitoring system 200, the isolation monitoring device 220 may help to facilitate timely interventions, such as alert generation or system adjustments, thereby enhancing the safety and efficiency of the vehicle subsystem 10.

In the example of FIG. 3, the energization may be achieved by means of a probe 130. The probe 130 may be operatively connected to the processing circuitry 110, e.g. the isolation resistance monitoring system 200, for selective energization. Probe may herein refer to an electrode, e.g. an electrode for receiving an electric current and energizing the coolant.

The vehicle 1, e.g. the vehicle subsystem 1, may comprise a switch 131 selectively connecting the probe 130 to a potential of the vehicle subsystem 10. Advantageously, the potential may be provided in the form of the poles 106, 107. The processing circuitry 110, e.g. the isolation resistance monitoring system 200, may be operatively connected to the switch 131 to control the switch 131 to selectively energize the probe 130 to thereby energize the coolant.

The probe 130 may be positioned to interact with the coolant within the fluid path 320. The probe 130 may thus be arranged to be exposed to the coolant within the fluid path 320. The probe 130 may be configured to energize the coolant, inducing a change between the first and second state. The energization process allows for a dynamic assessment of the system's electrical isolation properties, providing data for system monitoring.

Within the context of the present disclosure, the probe 130 may be configured to energize the coolant within the fluid path 320 to enable monitoring of electrical isolation in the vehicle subsystem 10. Various types of probes can be employed for this purpose.

A conductive probe can directly introduce an electrical charge into the coolant, allowing the system to assess changes in isolation resistance as the coolant becomes energized. This type of probe is effective for direct interaction with the fluid path, ensuring efficient distribution of electrical energy. An immersive electrode probe may also be suitable, designed to be submerged within the coolant to ensure uniform energization. This approach promotes consistent monitoring results by evenly distributing electrical energy throughout the fluid.

As aforementioned, the processing circuitry 110 may be operatively connected to the switch 131, enabling precise control over the energization of the probe 130. This setup enables that the coolant can be energized as needed, facilitating a responsive and adaptable monitoring system. The processing circuitry 110, e.g. the isolation resistance monitoring system 200, may be configured to control the switch 131 to cause switching between the first and second state of the fluid path 320.

In one example, a set resistance 135 may be arranged between the probe 130 and the power source 105. The set resistance 135 may thus be electrically connected to the probe 130 and the power source 105. This configuration may allow for the current flowing through the probe 130 to remain within safe limits, preventing potential overloading or damage to the system components. The inclusion of the set resistance 135 may thus enhance the safety and reliability of the energization process.

In the depicted example, the isolation monitoring device 220 is electrically connected to a conductor 115, e.g. a main DC-bus of the vehicle 1. The conductor 115 may electrically connect the poles 106, 107 and the ground connection 108.

In the depicted example, the conductor 115 serves as a main DC-bus within the vehicle 1. The conductor 115 may be configured to function as an electrical pathway facilitating the distribution of power across various components of the vehicle's electrical system, for example between the power source 105 and other components of the vehicle 1. By electrically connecting the poles 106, 107 and the ground connection 108, the conductor 115 may enable efficient power transfer and stability within the system.

In the depicted example, the vehicle subsystem 10 is provided as a battery system or a fuel cell system. The power source 105 may thus be a battery cell system or a fuel cell stack. The conductor 115 may be configured to distribute power from the power source 105 to other components of the vehicle 1.

As aforementioned the conductor 115 may be a main DC-bus. The main DC-bus may act as a centralized conduit for direct current, providing a stable and continuous flow of electricity to components of the vehicle 1. This centralized setup allows for effective management and distribution of electrical power.

In one example, any of the isolation monitoring device 220, the switch 130, the set resistance 135 may be integrated in a power source thermal system configured to control the cooling system 300. For example, the power source thermal system may be a battery thermal system or fuel cell thermal system.

As aforementioned, the isolation resistance monitoring system 200 may be configured to determine a faulty cooling system ground connection. In FIG. 3, a cooling system ground connection 390 is depicted. The isolation resistance monitoring system 200 may thus be configured to determine that the cooling system ground connection 390 is faulty based on the determined change in isolation resistance. The cooling system ground connection 390 may be a ground connection for one or more electrical component of the cooling system. In the depicted example, the cooling system ground connection 390 is electrically connected to the pump 395.

In the example depicted in FIG. 3, the change in isolation resistance may indicate that the probe 130, switch 131 or the set resistance 135 may be broken or that the connection to the cooling system ground connection 390 is broken in case a minimum expected change in isolation resistance is not observed.

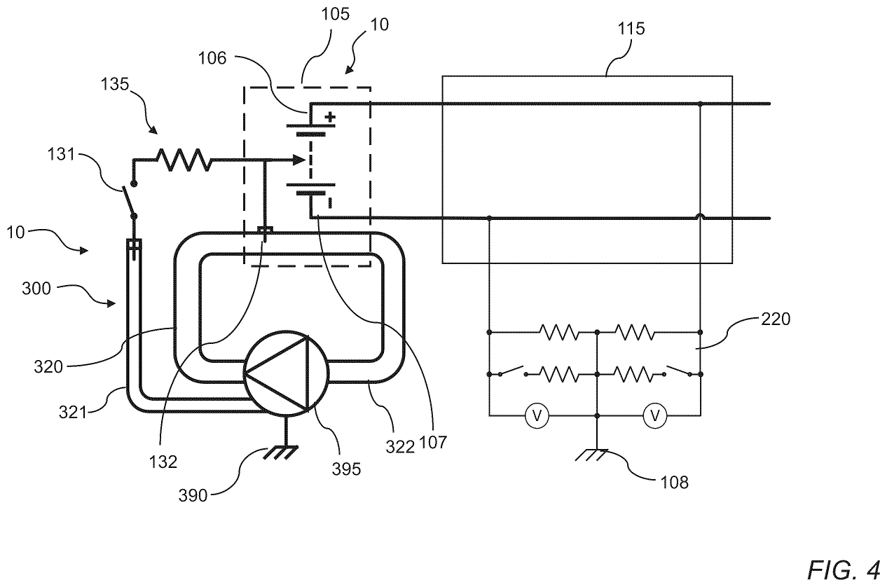

FIG. 4 illustrates a schematic representation of a vehicle subsystem 10 according to another example. In the example of FIG. 4, the coolant may already be exposed to the power source 105. Hence, the coolant is not isolated from the power source. In the depicted example, this is indicated by the electrical connection 132 between the fluid path 320 and the power source 105. The second section 322 may thus be in electrical connection with the power source 105. This may particularly be the case if the power source 105 is a fuel cell system or an immersion cooled battery system.

In the depicted example, the fluid path 320 comprises a first section 321 and a second section 322. The first section 321 and the second section 322 may be parallel to each other. The first section 321 may be in electric connection with the switch 131 such that activation of the switch causes the first section 321 to be electrically connected to the set resistance 135. The second section 322 may be electrically connected to the power source 105, e.g. via the electric connection 132. Hence, both the first state and the second state may be associated with the coolant in the fluid path 320 being energized.

Upon activation of the switch 131, the set resistance electrically connects the power source 105 and the first section 321 to the poles 106, 107 and the ground connection 108 such that the first section 321 is energized. Accordingly, in the first state, only the second section 322 may be energized and in the second state, both the first and the second section 321, 322 may be energized. Thus, a change in isolation resistance may be achieved.

The activation of the switch 131 may be performed responsive to an instruction from the isolation resistance monitoring system 200 or continuously.

In the depicted example, the switch 131 may form a part of the power source thermal system, e.g. a part of an electric circuitry of the power source thermal system. It may further be envisioned that the electric connection 132 and the switch 131 also may form a part of the power source thermal system.

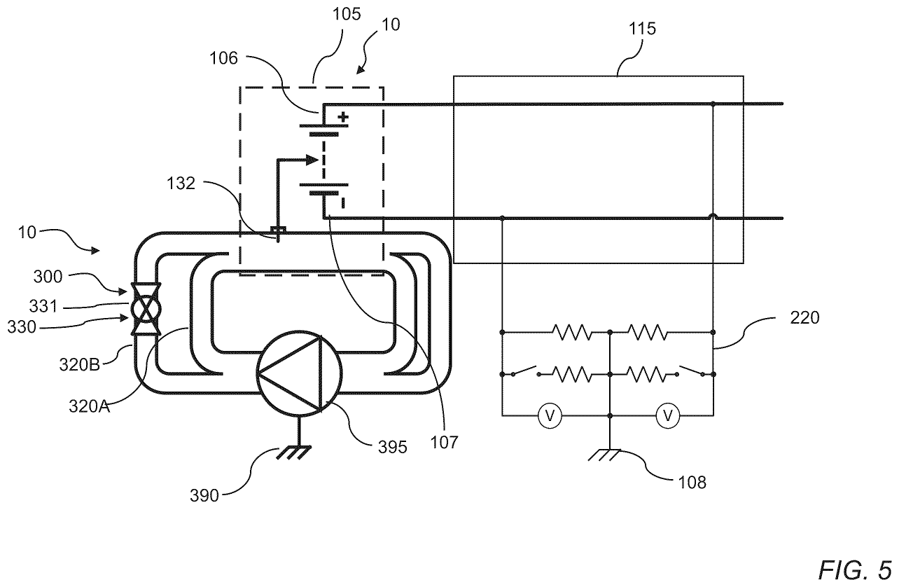

FIG. 5 illustrates a schematic representation of a vehicle subsystem 10 according to another example. The example highlights a manner of determining the change in isolation resistance responsive to a change in current flow. In the depicted example, the first and second state of the fluid path 320 is associated with a first and second geometrical characteristic, respectively.

In the depicted example, the vehicle 1, e.g. the vehicle subsystem 10, may comprise a flow adjusting device 330. The flow adjusting device 330 may be arranged in the fluid path 320 to cause a change in the geometric characteristics of the coolant path 320 between the first state and the second state.

In the example of FIG. 5, the coolant may already be exposed to the power source 105. Hence, the coolant is not isolated from the power source. In the depicted example, this is indicated by the electrical connection 132 between the fluid path 320 and the power source 105.

Due to the coolant being energized, the flow adjusting device 330 may be configured to control the current flow through the fluid patch 320. For example, in the event of the flow adjusting device 330 sealing off a section of fluid path 320, the sealed off section may be removed from a baseline total resistance (associated with the first state) while the remaining section(s) of the fluid patch 320 remains part of that baseline total resistance (associated with the second state) which can be assumed constant over the change.

The processing circuitry 110, e.g. the isolation resistance monitoring system 200, may be configured to control the flow adjusting device 330 to cause a change in the geometric characteristics of the coolant path 320 between the first state and the second state.

The change in the geometric characteristics of the coolant path 320 and the resulting change in isolation resistance may be utilized to generate the previously described control data.

Referencing FIG. 5, the flow adjusting device 330 may be a component within the cooling system 300. The flow adjusting device 330 may be positioned in the fluid path 320 to facilitate a change in the geometric characteristics of the coolant path 320 thereby causing transitioning between a first and second state without the need to selectively energize the coolant. Various examples of flow adjusting devices may be considered to achieve this functionality.

In some examples, the flow adjusting device 330 may comprise a variable valve mechanism 331. The variable valve mechanism 331 may be configured to control the flow rate of the coolant within the fluid path 320. The processing circuitry 110, e.g. the isolation resistance monitoring system 200, may be configured to control the position of the variable valve mechanism 331 to change the geometric characteristics of the fluid path 320. By altering the position of the variable valve mechanism 331, e.g. the position of a valve member of the variable valve mechanism 331, the pathway of the coolant through the fluid path 320 is adjusted causing a change between the first and second state. Thereby, the geometric characteristics are changed, potentially impacting the isolation resistance measurements.

In some examples, the flow adjusting device 330 may comprise an adjustable baffle system arranged in the fluid path 320. These baffles can be repositioned or reoriented to modify the flow pattern and turbulence of the coolant, influencing the overall geometry of the path.

In some examples, the flow adjusting device 330 may comprise one or more multi-way valves configured to control the flow of coolant between flow paths. The flow paths may have different resistances and/or different lengths relative to the ground.

In some examples, the flow adjusting device 330 may comprise a flexible tubing system that can be expanded or contract by means of being engaged by an actuating system in response to control signals from the processing circuitry 110, e.g. the isolation resistance monitoring system 200. This flexibility allows for dynamic changes in the coolant path's shape and/or length, facilitating the monitoring of isolation resistance changes as the geometric characteristics vary.

To cause actuation of for example flexible tubing or the adjustable baffle system, the flow adjusting device 330 may comprise an actuator system such as an electromechanical actuator system. The actuator system may be configured to actuate the adjustable baffle system and/or the flexible tubing system to alter the flow path of the fluid path 320. This may enable targeted adjustments to the coolant path, enhancing the system's ability to detect changes in isolation resistance effectively.

In the depicted example, the fluid path 320 comprises two parallel and interconnected fluid path sections 320A-B. A first fluid path section 320A may be in fluid communication with a second fluid path section 320B and may be arranged in parallel to said second fluid path section 320B. The flow adjusting device 330 may be arranged in the second fluid path section 320B and be configured to control the flow in said second fluid path section 320B to cause the fluid path 320 to switch between operating in the first state and the second state.

The second fluid path section 320B may be selectively sealed off by means of the flow adjusting device 330. In the first state, the flow adjusting device 330 may be configured to seal off the second fluid path section 320B. In the second state, the flow adjusting device 330 may be configured to enable flow through the second fluid path section 320B, thereby altering the geometric characteristics of the fluid path 320.

In the depicted example, the coolant may be energized. In the first state, the coolant will only flow through the first fluid path section 320A due to flow adjusting device 330 blocking passage into the second fluid path section 320B, resulting in a first determined isolation resistance between the poles 106, 107 and the ground connection 108. The processing circuitry 110, e.g. the isolation resistance monitoring system 200, may then cause the switch from the first state to the second state by controlling the flow adjusting device 330 to enable passage of coolant into the second fluid path section 320B. This results in a second determined isolation resistance between the poles 106, 107 and the ground connection 108.

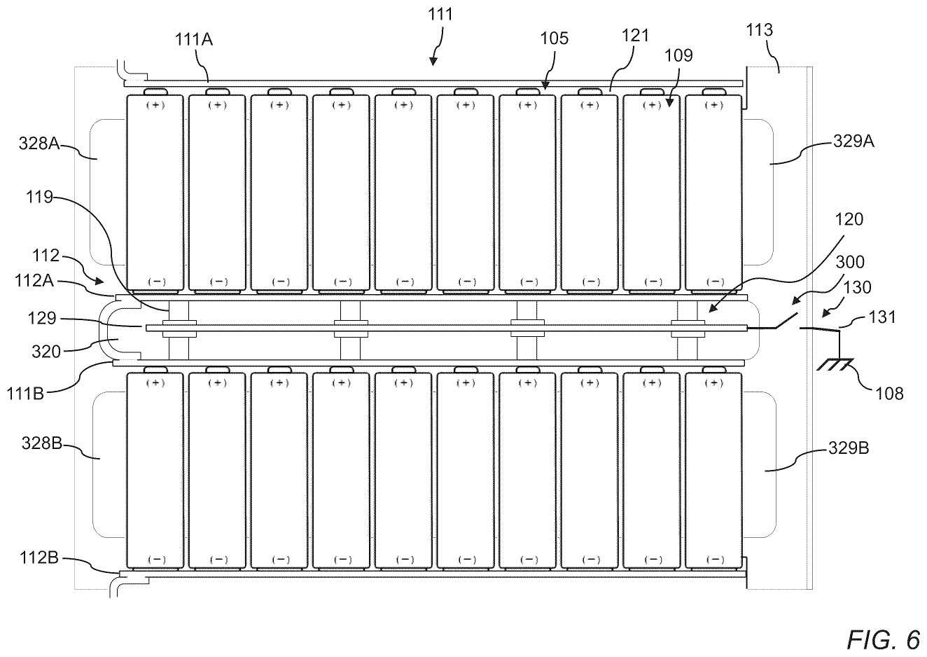

FIG. 6 depicts a vehicle subsystem 10 according to another example. In the depicted example, the vehicle subsystem 10 is formed by a battery system and in particular an immersion cooled battery system. Accordingly, the battery system 10 may comprise one or more immersion cooled batteries 109. Further, the cooling system 300 may be provided as an immersion cooling system.

The depicted example highlights an approach to thermal management, where one or more immersion cooled batteries 109 are integrated into the cooling system 300, provided as an immersion cooling system.

Within this system, the fluid path 320 may be configured to circulate coolant in the form a dielectric fluid around the immersion cooled batteries 109. The one or more immersion cooled batteries 109 may thus be arranged in the fluid path 320. The fluid path 320 may serve to remove or supply heat to or from the immersion cooled batteries 109 for maintaining desirable operating temperatures and enhancing the performance and longevity of the battery system. As the coolant circulates through the fluid path 320, the coolant absorbs heat from the immersion cooled batteries 109 and carries it away from critical components. By directly surrounding the immersion cooled batteries 109 with the coolant within the fluid path 320, the system may reduce the occurrences of hotspots and improve thermal management. This approach may be particularly advantageous in high-performance applications, supporting the reliable operation and safety of the vehicle subsystem 10.

Further referencing FIG. 6, the vehicle 1, e.g. the vehicle subsystem 10 herein provided as a battery system, comprises a shielding 113, a conductor 115 or a collector plate 129. The shielding 113, the conductor 115 or collector plate 129 may form the probe 130. The shielding, the conductor or collector plate may be arranged adjacent to an area of similar voltage potential within the immersion cooled batteries 109. A shielding, conductor or collector plate commonly forms a part of a battery system and in particular an immersion cooled battery system. Thus, this may allow for monitoring of the isolation resistance in a manner not requiring a surplus of additional components. In the depicted example, the conductor may be provided in the form of a busbar.

In the depicted example, the vehicle 1, e.g. the vehicle subsystem 10, comprises an additional conductor or collector plate 129 functioning as a probe 130 as previously described. The conductor or collector plate 129 may be provided in addition to a cathode collector plate 111 and an anode collector plate 112 electrically connected to the poles of the one or more immersion cooled batteries 109. The conductor or collector plate 129 may be arranged such that it has substantially the same or at least similar potential compared to the anode collector plate 112 and the cathode collector plate 111. The conductor or collector plate 129 may thus normally float with the same potential as the adjacent anode/cathode collector plates 111, 112 but presents an isolation fault proportional to the constant geometry and variable conductivity when bonded to the ground connection 108. In the depicted example, the conductor or collector plate 129 is arranged proximal to the anode collector plate 112.

To exemplify, at the cell level, exposure may be to a number of similar potentials to generate a significant area from a plurality of small areas or alternatively it may be a large area provided at one potential level. At the pack/stack level this could for example be at a mid-potential in which case if at one single level then the cathode potential of one stack or module of cells is the anode level of the next stack or module of cells.

Further referencing FIG. 6, the conductor or collector plate 129 may be separated from the anode collector plate 112 or cathode collector plate 111 by means of one or more insulating spacers 119. It may be envisioned that one or more insulating spacers 119 comprises one or more spacer elements arranged between the conductor or collector plate 129 and the anode collector plate 112 or the cathode collector plate 111. In another example, the one or more insulating spacers 119 may comprise an insulating and perforated plate. Notably, any type of conventional insulating spacers 119 may be utilized provided that said insulating spacer 119 provides exposure to the coolant in the fluid path 320 for the conductor or collector plate 129.

In the depicted example, the conductor or collector plate 129 is selectively connectable to the ground connection 108 by means of the switch 131. Hence, the switch 131 may be configured to cause the fluid path 320 to switch between operating in the first and the second state by means of connecting and disconnecting the conductor or collector plate 129 to and from the ground connection 108. In one example the switch 131 may be provided as a contactor. In one example, the switch 131 may comprise a relay for feed-though for bonding to the ground connection 108. In one example, the switch 131 may comprise an internal armature driven by an electromagnet or hermitic solenoid or similar. This may allow for a switch 131 which is highly localized and/or galvanically isolated which may improve life and safety should it need to be serviced.

The ground connection 108 may in one example be bonded to the chassis of the vehicle 1. The ground connection 108 may for example be welded to the chassis. In one example, the ground connection 108 may be bonded to the chassis or enclosure of the power source 105, e.g. the battery system or fuel cell system.

Referencing FIG. 6, the battery system may comprise a plurality of modules each comprising one or more immersion cooled battery 109. In one example, a conductor or collector plate 129 functioning as a probe 130 may be inserted at a substantially middle potential location in the series of (parallel cell) modules making up the battery pack of the battery system so as to generate a symmetric isolation fault. Alternatively, the conductor or collector plate 129 may be arranged to be offset towards or located at one of the poles to get an intentionally asymmetric fault. The system with the switch 131 and the conductor or collector plate 129 may be considered a measuring cell. For example, two or more measuring cells may be utilized to get more information and also to have the possibility to select fault size by varying the number of faults used simultaneously.

In the depicted example, the conductor or collector plate 129 is arranged at a substantially middle potential location, e.g. between the anode collector plate 112A of a first battery module and a cathode collector plate 111B of a second battery module. Isolation spacers 119 are arranged to separate the conductor or collector plate 129 from said anode collector plate 112A and cathode collector plate 111B.

In the depicted example, the fluid path 320 may comprise an inlet 328 and outlet 329. Advantageously, the fluid path 320 may comprise an inlet and outlet for each battery module for distributing coolant for immersing the one or more immersion cooled batteries 109 of said battery module. Accordingly, the fluid path 320 may comprise a first inlet 328A configured to receive coolant for immersing the one or more immersion cooled batteries of the first battery module and a first outlet 329A for guiding the coolant away from the fluid path 302 and the first battery module. Similarly, the fluid path 320 may comprise a second inlet 328B configured to receive coolant for immersing the one or more immersion cooled batteries of the second battery module and a second outlet 329B for guiding the coolant away from the fluid path 302 and the second battery module.

As depicted in FIG. 6, the battery system, e.g. the immersion cooled battery system, may comprise the shielding 113. The shielding 113 may be in an insulating material and may be configured to encapsulate the battery system. The one or more inlet 328 and one or more outlet 329 may extend through the shielding 113.

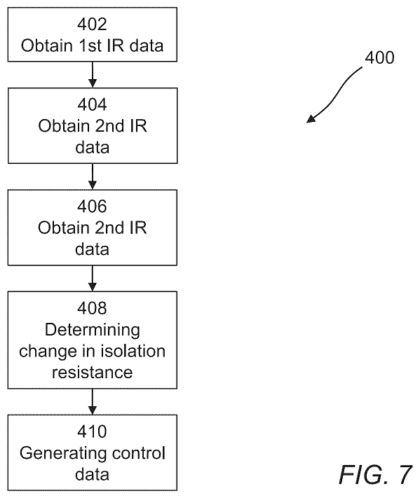

FIG. 7 is a flow chart of a method 400 for determining a change in isolation resistance according to an example. The method 400 may be a computer-implemented method.

The method 400 comprises obtaining 402, by processing circuitry of a computer system, first isolation resistance data associated with an isolation resistance between poles 106, 107 of vehicle subsystem 10 of a vehicle 1 and a ground connection 108, wherein a fluid path 320 of a cooling system 300 configured to cool the vehicle subsystem 10 is in a first state.

The method 400 further comprises obtaining 404, by the processing circuitry, second isolation resistance data associated with an isolation resistance between the poles 106, 107 and the ground connection 108 wherein the fluid path 320 is in a second state, wherein coolant in the fluid path 320 is electrically energized in at least the second state.

The method 400 further comprises determining 408, by the processing circuitry, a change in isolation resistance between the poles 106, 107 and the ground connection 108 based on the first and second isolation resistance data.

The method 400 further comprises generating 410, by the processing circuitry, control data for the vehicle 1 based on the determined change.

Optionally, the method 400 may comprise obtaining, by the processing circuitry, fluid path resistance data associated with the electrical resistance of the fluid path 320 and generating 410, by the processing circuitry, control data based for the vehicle 1 based on the determined change in isolation resistance and the fluid path resistance data.

Optionally, the method 400 may comprise responsive to the determined change in isolation resistance being outside a coolant isolation resistance threshold, determining, by the processing circuitry, that the fluid path 320 leaks into the vehicle subsystem 10.

FIG. 8 is a schematic diagram of a computer system 800 for implementing examples disclosed herein. The computer system 800 is adapted to execute instructions from a computer-readable medium to perform these and/or any of the functions or processing described herein. The computer system 800 may be connected (e.g., networked) to other machines in a LAN (Local Area Network), LIN (Local Interconnect Network), automotive network communication protocol (e.g., FlexRay), an intranet, an extranet, or the Internet. While only a single device is illustrated, the computer system 800 may include any collection of devices that individually or jointly execute a set (or multiple sets) of instructions to perform any one or more of the methodologies discussed herein. Accordingly, any reference in the disclosure and/or claims to a computer system, computing system, computer device, computing device, control system, control unit, electronic control unit (ECU), processor device, processing circuitry, etc., includes reference to one or more such devices to individually or jointly execute a set (or multiple sets) of instructions to perform any one or more of the methodologies discussed herein. For example, control system may include a single control unit or a plurality of control units connected or otherwise communicatively coupled to each other, such that any performed function may be distributed between the control units as desired. Further, such devices may communicate with each other or other devices by various system architectures, such as directly or via a Controller Area Network (CAN) bus, etc.

The computer system 800 may comprise at least one computing device or electronic device capable of including firmware, hardware, and/or executing software instructions to implement the functionality described herein. The computer system 800 may include processing circuitry 802 (e.g., processing circuitry including one or more processor devices or control units), a memory 804, and a system bus 806. The computer system 800 may include at least one computing device having the processing circuitry 802. The system bus 806 provides an interface for system components including, but not limited to, the memory 804 and the processing circuitry 802. The processing circuitry 802 may include any number of hardware components for conducting data or signal processing or for executing computer code stored in memory 804. The processing circuitry 802 may, for example, include a general-purpose processor, an application specific processor, a Digital Signal Processor (DSP), an Application Specific Integrated Circuit (ASIC), a Field Programmable Gate Array (FPGA), a circuit containing processing components, a group of distributed processing components, a group of distributed computers configured for processing, or other programmable logic device, discrete gate or transistor logic, discrete hardware components, or any combination thereof designed to perform the functions described herein. The processing circuitry 802 may further include computer executable code that controls operation of the programmable device.

The system bus 806 may be any of several types of bus structures that may further interconnect to a memory bus (with or without a memory controller), a peripheral bus, and/or a local bus using any of a variety of bus architectures. The memory 804 may be one or more devices for storing data and/or computer code for completing or facilitating methods described herein. The memory 804 may include database components, object code components, script components, or other types of information structure for supporting the various activities herein. Any distributed or local memory device may be utilized with the systems and methods of this description. The memory 804 may be communicably connected to the processing circuitry 802 (e.g., via a circuit or any other wired, wireless, or network connection) and may include computer code for executing one or more processes described herein. The memory 804 may include non-volatile memory 808 (e.g., read-only memory (ROM), erasable programmable read-only memory (EPROM), electrically erasable programmable read-only memory (EEPROM), etc.), and volatile memory 810 (e.g., random-access memory (RAM)), or any other medium which can be used to carry or store desired program code in the form of machine-executable instructions or data structures and which can be accessed by a computer or other machine with processing circuitry 802. A basic input/output system (BIOS) 812 may be stored in the non-volatile memory 808 and can include the basic routines that help to transfer information between elements within the computer system 800.

The computer system 800 may further include or be coupled to a non-transitory computer-readable storage medium such as the storage device 814, which may comprise, for example, an internal or external hard disk drive (HDD) (e.g., enhanced integrated drive electronics (EIDE) or serial advanced technology attachment (SATA)), HDD (e.g., EIDE or SATA) for storage, flash memory, or the like. The storage device 814 and other drives associated with computer-readable media and computer-usable media may provide non-volatile storage of data, data structures, computer-executable instructions, and the like.

Computer-code which is hard or soft coded may be provided in the form of one or more modules. The module(s) can be implemented as software and/or hard-coded in circuitry to implement the functionality described herein in whole or in part. The modules may be stored in the storage device 814 and/or in the volatile memory 810, which may include an operating system 816 and/or one or more program modules 818. All or a portion of the examples disclosed herein may be implemented as a computer program 820 stored on a transitory or non-transitory computer-usable or computer-readable storage medium (e.g., single medium or multiple media), such as the storage device 814, which includes complex programming instructions (e.g., complex computer-readable program code) to cause the processing circuitry 802 to carry out actions described herein. Thus, the computer-readable program code of the computer program 820 can comprise software instructions for implementing the functionality of the examples described herein when executed by the processing circuitry 802. In some examples, the storage device 814 may be a computer program product (e.g., readable storage medium) storing the computer program 820 thereon, where at least a portion of a computer program 820 may be loadable (e.g., into a processor) for implementing the functionality of the examples described herein when executed by the processing circuitry 802. The processing circuitry 802 may serve as a controller or control system for the computer system 800 that is to implement the functionality described herein.

The computer system 800 may include an input device interface 822 configured to receive input and selections to be communicated to the computer system 800 when executing instructions, such as from a keyboard, mouse, touch-sensitive surface, etc. Such input devices may be connected to the processing circuitry 802 through the input device interface 822 coupled to the system bus 806 but can be connected through other interfaces, such as a parallel port, an Institute of Electrical and Electronic Engineers (IEEE) 1394 serial port, a Universal Serial Bus (USB) port, an IR interface, and the like. The computer system 800 may include an output device interface 824 configured to forward output, such as to a display, a video display unit (e.g., a liquid crystal display (LCD) or a cathode ray tube (CRT)). The computer system 800 may include a communications interface 826 suitable for communicating with a network as appropriate or desired.

The operational actions described in any of the exemplary aspects herein are described to provide examples and discussion. The actions may be performed by hardware components, may be embodied in machine-executable instructions to cause a processor to perform the actions, or may be performed by a combination of hardware and software. Although a specific order of method actions may be shown or described, the order of the actions may differ. In addition, two or more actions may be performed concurrently or with partial concurrence.

According to an aspect, a computer system, vehicle, method, computer program product and non-transitory computer-readable storage medium according to any of the following examples provided.
Example 1: Computer system comprising processing circuitry configured to: obtain first isolation resistance data associated with an isolation resistance between poles (106, 107) of a vehicle subsystem (10) of a vehicle (1) and a ground connection (108) wherein a fluid path (320) of a cooling system (300) configured to cool the vehicle subsystem (10) is in a first state, obtain second isolation resistance data associated with an isolation resistance between the poles (106, 107) and the ground connection (108) wherein the fluid path (320) is in a second state, wherein coolant in the fluid path (320) is electrically energized at least in the second state, and determine a change in isolation resistance between the poles (106, 107) and the ground connection (108) based on the first and second isolation resistance data, and generate control data for the vehicle (1) based on the determined change.
Example 2: Computer system of example 1, wherein the processing circuitry is further configured to: obtain fluid path resistance data associated with the electrical resistance of the fluid path (320), and generate control data for the vehicle (1) based on the determined change in isolation resistance and the fluid path resistance data.
Example 3: Computer system of any of examples 1-2, wherein the processing circuitry is further configured to: responsive to the determined change in isolation resistance being outside a fluid path isolation resistance threshold, determine that the fluid path (320) leaks into the vehicle subsystem (10).
Example 4: Computer system of any of examples 1-3, wherein the processing circuitry is further configured to: responsive to the determined change in isolation resistance being outside a fault resistance threshold, determine that a fault is present in at least one of the vehicle subsystem (10) and the cooling system (300).
Example 5: Computer system of any of examples 2-4, wherein the processing circuitry is further configured to: obtain the fluid path resistance data based on geometrical characteristics of the fluid path (320) and/or characteristics of the coolant.
Example 6: Computer system of any of examples 1-5, wherein the processing circuitry is further configured to: obtain a diagnostic or fault tracing command, and responsive to the diagnostic or fault tracing command cause a switch between the first and second state.
Example 7: Computer system of any of examples 1-6, wherein the processing circuitry is further configured to: cause a change between the first and the second state via a probe (130) exposed to the coolant.
Example 8: Computer system of any of examples 1-7, wherein the processing circuitry is further configured to: control a flow adjusting device (330) arranged in the fluid path (320) to cause a change in the geometric characteristics of the coolant path (320) between the first state and the second state.
Example 9: A vehicle (1) comprising the computer system of any of examples 1-8.
Example 10: The vehicle (1) of example 9, further comprising an isolation monitoring device (220) operatively connected to the processing circuitry and configured to measure the isolation between the poles (106, 107) and the ground connection (108) to provide the first and second isolation resistance data.
Example 11: The vehicle (1) of example 9 or 10, further comprising a switch (131) selectively connecting a probe (130) to a potential of the vehicle subsystem (10), such as the poles (106, 107), wherein the processing circuitry is operatively connected to the switch (131) to control said switch (131) to selectively energize the probe (130) to thereby energize the coolant.
Example 12: The vehicle (1) of any of examples 9-11, further comprising a set resistance (135) arranged between the probe (130) and a power source (105) for energizing the probe (130).
Example 13: The vehicle (1) of any of examples 9-12, further comprising at least one fuel cell system forming the vehicle subsystem.
Example 14: The vehicle (1) of any of examples 9-12, further comprising at least one battery system forming the vehicle subsystem.
Example 15: The vehicle (1) of example 14, wherein the battery system comprises one or more immersion cooled batteries (109) and the cooling system (300) is provided as an immersion cooling system.
Example 16: The vehicle (1) of example 15, further comprising a shielding, conductor (115) or collector plate (129), wherein said shielding, conductor or collector plate (129) forms the probe (130) and is arranged adjacent to an area of similar voltage potential of the one or more immersion cooled batteries (109).
Example 17: The vehicle (1) of any of examples 9-12, further comprising at least one motor drive system forming the vehicle subsystem.
Example 18: The vehicle (1) of example 9, further comprising at least one battery system and/or fuel cell system forming the vehicle subsystem, wherein the processing circuitry is further configured to: energizing the coolant in the fluid path (320) via a probe (130) exposed to the coolant to cause a change in energization between the first state and the second state, obtain fluid path resistance data associated with the electrical resistance of the fluid path (320), generate control data for the vehicle (1) based on the determined change in isolation resistance and the fluid path resistance data, and responsive to the determined change in isolation resistance being outside a fluid path isolation resistance threshold, determine that the fluid path (320) leaks into the vehicle subsystem (10).
Example 19: A computer-implemented method comprising: obtaining, by processing circuitry of a computer system, first isolation resistance data associated with an isolation resistance between poles (106, 107) of a vehicle subsystem (10) of a vehicle (1) and a ground connection (108), wherein a fluid path (320) of a cooling system (300) configured to cool the vehicle subsystem (10) is in a first state, obtaining, by the processing circuitry, second isolation resistance data associated with an isolation resistance between the poles (106, 107) and the ground connection (108) wherein the fluid path (320) is in a second state, wherein coolant in the fluid path (320) is electrically energized in at least the second state, determining, by the processing circuitry, a change in isolation resistance between the poles (106, 107) and the ground connection (108) based on the first and second isolation resistance data, and generating, by the processing circuitry, control data for the vehicle (1) based on the determined change.
Example 20: Computer-implemented method of example 19, further comprising: obtaining, by the processing circuitry, fluid path resistance data associated with the electrical resistance of the fluid path (320), and generating, by the processing circuitry, control data for the vehicle (1) based on the determined change in isolation resistance and the fluid path resistance data.
Example 21: Computer-implemented method of example 20, further comprising: responsive to the determined change in isolation resistance being outside a coolant isolation resistance threshold, determine, by the processing circuitry, that the fluid path (320) leaks into the vehicle subsystem (10).
Example 22: A computer program product comprising program code for performing, when executed by the processing circuitry, the method of any of examples 19-21.
Example 23: A non-transitory computer-readable storage medium comprising instructions, which when executed by the processing circuitry, cause the processing circuitry to perform the method of any of examples 19-21.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. As used herein, the term “and/or” includes any and all combinations of one or more of the associated listed items. It will be further understood that the terms “comprises,” “comprising,” “includes,” and/or “including” when used herein specify the presence of stated features, integers, actions, steps, operations, elements, and/or components, but do not preclude the presence or addition of one or more other features, integers, actions, steps, operations, elements, components, and/or groups thereof.

It will be understood that, although the terms first, second, etc., may be used herein to describe various elements, these elements should not be limited by these terms. These terms are only used to distinguish one element from another. For example, a first element could be termed a second element, and, similarly, a second element could be termed a first element without departing from the scope of the present disclosure.

Relative terms such as “below” or “above” or “upper” or “lower” or “horizontal” or “vertical” may be used herein to describe a relationship of one element to another element as illustrated in the Figures. It will be understood that these terms and those discussed above are intended to encompass different orientations of the device in addition to the orientation depicted in the Figures. It will be understood that when an element is referred to as being “connected” or “coupled” to another element, it can be directly connected or coupled to the other element, or intervening elements may be present. In contrast, when an element is referred to as being “directly connected” or “directly coupled” to another element, there are no intervening elements present.

Unless otherwise defined, all terms (including technical and scientific terms) used herein have the same meaning as commonly understood by one of ordinary skill in the art to which this disclosure belongs. It will be further understood that terms used herein should be interpreted as having a meaning consistent with their meaning in the context of this specification and the relevant art and will not be interpreted in an idealized or overly formal sense unless expressly so defined herein.

It is to be understood that the present disclosure is not limited to the aspects described above and illustrated in the drawings; rather, the skilled person will recognize that many changes and modifications may be made within the scope of the present disclosure and appended claims. In the drawings and specification, there have been disclosed aspects for purposes of illustration only and not for purposes of limitation, the scope of the disclosure being set forth in the following claims.

What is claimed is:

1. A computer system comprising processing circuitry configured to:
obtain first isolation resistance data associated with an isolation resistance between poles of a vehicle subsystem of a vehicle and a ground connection wherein a fluid path of a cooling system configured to cool the vehicle subsystem is in a first state, obtain second isolation resistance data associated with an isolation resistance between the poles and the ground connection wherein the fluid path is in a second state, wherein coolant in the fluid path is electrically energized at least in the second state, and
determine a change in isolation resistance between the poles and the ground connection based on the first and second isolation resistance data, and
generate control data for the vehicle based on the determined change.

2. The computer system of claim 1, wherein the processing circuitry is further configured to:
obtain fluid path resistance data associated with the electrical resistance of the fluid path, and
generate control data for the vehicle based on the determined change in isolation resistance and the fluid path resistance data.

3. The computer system of claim 1, wherein the processing circuitry is further configured to:
responsive to the determined change in isolation resistance being outside a fluid path isolation resistance threshold, determine at least one of that the fluid path leaks into the vehicle subsystem and that contamination has occurred in the vehicle subsystem.

4. The computer system of claim 1, wherein the processing circuitry is further configured to:
responsive to the determined change in isolation resistance being outside a fault resistance threshold, determine that a fault is present in at least one of the vehicle subsystem and the cooling system.

5. The computer system of claim 2, wherein the processing circuitry is further configured to:
obtain the fluid path resistance data based on geometrical characteristics of the fluid path and/or characteristics of the coolant.

6. The computer system of claim 1, wherein the processing circuitry is further configured to: obtain a diagnostic or fault tracing command, and responsive to the diagnostic or fault tracing command cause a switch between the first and second state.

7. The computer system of claim 1, wherein the processing circuitry is further configured to:
cause a change between the first and the second state via a probe exposed to the coolant.

8. The computer system of claim 1, wherein the processing circuitry is further configured to:
control a flow adjusting device arranged in the fluid path to cause a change in the geometric characteristics of the coolant path between the first state and the second state.

9. A vehicle comprising the computer system of claim 1.

10. The vehicle of claim 9, further comprising an isolation monitoring device operatively connected to the processing circuitry and configured to measure the isolation between the poles and the ground connection to provide the first and second isolation resistance data.

11. The vehicle of claim 9, further comprising a switch selectively connecting a probe to a potential of the vehicle subsystem, such as the poles, wherein the processing circuitry is operatively connected to the switch to control said switch to selectively energize the probe to thereby energize the coolant.

12. The vehicle of claim 9, further comprising a set resistance arranged between the probe and a power source for energizing the probe.

13. The vehicle of claim 9, further comprising at least one fuel cell system forming the vehicle subsystem.

14. The vehicle of claim 9, further comprising at least one battery system forming the vehicle subsystem.

15. The vehicle of claim 14, wherein the battery system comprises one or more immersion cooled batteries and the cooling system is provided as an immersion cooling system.

16. The vehicle of claim 9, further comprising at least one battery system forming the vehicle subsystem, wherein the battery system comprises one or more immersion cooled batteries and the cooling system is provided as an immersion cooling system, the vehicle further comprising a shielding, conductor or collector plate, wherein said shielding, conductor or collector plate forms the probe and is arranged adjacent to an area of similar voltage potential of the one or more immersion cooled batteries.

17. The vehicle of claim 9, further comprising at least one battery system and/or fuel cell system forming the vehicle subsystem, wherein the processing circuitry is further configured to:
energizing the coolant in the fluid path via a probe exposed to the coolant to cause a change in energization between the first state and the second state,
obtain fluid path resistance data associated with the electrical resistance of the fluid path,
generate control data for the vehicle based on the determined change in isolation resistance and the fluid path resistance data, and
responsive to the determined change in isolation resistance being outside a fluid path isolation resistance threshold, determine that the fluid path leaks into the vehicle subsystem.

18. A computer-implemented method comprising:
obtaining, by processing circuitry of a computer system, first isolation resistance data associated with an isolation resistance between poles of a vehicle subsystem of a vehicle and a ground connection, wherein a fluid path of a cooling system configured to cool the vehicle subsystem is in a first state,
obtaining, by the processing circuitry, second isolation resistance data associated with an isolation resistance between the poles and the ground connection wherein the fluid path is in a second state, wherein coolant in the fluid path is electrically energized in at least the second state,
determining, by the processing circuitry, a change in isolation resistance between the poles and the ground connection based on the first and second isolation resistance data, and
generating, by the processing circuitry, control data for the vehicle based on the determined change.

19. A computer program product comprising program code for performing, when executed by the processing circuitry, the method of claim 18.

20. A non-transitory computer-readable storage medium comprising instructions, which when executed by the processing circuitry, cause the processing circuitry to perform the method of claim 18.
